(19) United States
(12) Patent Application Publication
(10) Pub. No.: US 2007/0290196 A1
(43) Pub. Date: Dec. 20, 2007

(54) ORGANIC LIGHT EMITTING DISPLAY DEVICE AND METHOD FOR MANUFACTURING THE ORGANIC LIGHT EMITTING DISPLAY DEVICE

(75) Inventors: Joerg FISCHER, Berlin (DE); Arthur MATHEA, Berlin (DE); Michael REDECKER, Berlin (DE)

Correspondence Address: H.C. PARK & ASSOCIATES, PLC, 8500 LEESBURG PIKE, SUITE 7500, VIENNA, VA, 22182, US

(73) Assignees: SAMSUNG SDI CO., LTD., Suwon-si (KR); SAMSUNG SDI GERMANY GMBH, Berlin (DE)

(21) Appl. No.: 11/456,343

(22) Filed: Jul. 10, 2006

(30) Foreign Application Priority Data
Jul. 8, 2005 (DE) 10-2005-032741.9
May 9, 2006 (KR) 10-2006-0041603

(51) Int. Cl. H01L 51/05; H01L 51/40; H01L 51/50

(52) U.S. Cl. 257/40; 438/22; 257/E51.022; 257/E51.006

(57) ABSTRACT

An organic light emitting display device has thin film transistors. An organic thin film transistor (OTFT) is manufactured in one substrate and an organic light emitting diode (OLED) is manufactured on the other substrate, and the first substrate and second substrate are then positioned to face each other. The first substrate and the second substrate are electrically coupled together by contacts positioned on the first substrate, the second substrate, or both. OTFT is manufactured using a dispenser or ink jet printing method, reducing manufacturing time and costs.

### CROSS REFERENCE TO RELATED APPLICATIONS

This application claims priority to and the benefit of German Patent Application No. 102005032741.9, filed on Jul. 8, 2005, and Korean Patent Application No. 10-2006-0041603, filed on May 9, 2006, which are hereby incorporated by reference for all purposes as if fully set forth herein.

### BACKGROUND OF THE INVENTION

1. Field of the Invention

The present invention relates to an organic light emitting display device and a method for manufacturing the organic light emitting display device. More particularly, the present invention relates to a simply flexible active matrix (AM) type organic light emitting display device (AMOLED) and a method for manufacturing the simply flexible active matrix (AM) type organic light emitting display device.

2. Discussion of the Background

In manufacturing a flat panel display device, cost is a very important factor. Many manufacturers want to produce a high quality display at a lower cost. As a prominent type of new display technology, organic thin film transistors (OTFTs) have been used for an active control in organic light emitting display devices.

Active matrix (AM) type organic light emitting display devices have been using multiplexing of activation circuits. Organic light emitting display devices have two types, a small molecule type or a high-polymer type, depending on the type of light emitting layer. Conventional AM type pixels may have a transistor made of silicon, which is inorganic, or of organic semiconductor material. The organic thin film transistor uses organic semiconductor material to form a thin film transistor. Therefore, transistors can include the organic semiconductor material and an inorganic material, or both materials. Solution and low-temperature processes of both materials can be possible.

EP 0717445 discloses an AM type display comprising organic light emitting device pixels. WO/2003/071511 discloses an AMOLED display that perpendicularly arranges capacitors in order to prevent the decrease in an aperture ratio of the AMOLED display when two or more capacitors are required. However, since devices such as transistors are disposed near the displays, the aperture ratio is not high.

A typical arrangement of pixels is an n-channel or p-channel MOSFET. Polycrystalline, amorphous, or mono-crystalline silicon can be used for the MOSFETs. For example, U.S. Pat. No. 6,157,356 discloses a basic organic light emitting device structure having two transistor circuits. The inorganic transistor, however, requires capital intensive semiconductor manufacturing technology.

Display technologies such as an electrophoretic, electro-chrome, or liquid crystal display can use organic semiconductor matrix. WO/99/53371 discloses a display having a sealed display medium using the OTFT.

Theoretically, to operate an OLED display, a transistor requires a charge mobility in the range of about 1 cm²/Vs to about 10 cm²/Vs. The charge mobility of an organic transistor may be about 5 cm²/Vs. The OLED display comprising those transistors can be manufactured in the near future. An organic transistor can be formed on a second substrate (a substrate comprising OTFT function layers), using direct-structuring technology such as a low temperature production process, or inkjet printing. This would considerably reduce manufacturing costs.

WO/2003/098696 discloses a method for manufacturing an electro-optical device circuit using the inkjet technology.

An OTFT circuit and/or OLED display driver device is widely known from some publications.

WO/2003/056640 discloses a display that has an organic light emitting diode (OLED) and OTFT disposed on a substrate. The OLED is disposed in a lower part of the OTFT. However, OLED material's sensitive characteristics may limit the way how to manufacture OTFT. For example, the OLED can only be manufactured at a low temperature, which restricts the selection of the OTFT material.

WO/99/54936 discloses an integrated circuit using a semiconductor polymer material as a switching device. An organic display device is disposed in an electrode of the switching device.

EP 1246244 discloses an AM display comprising the OLED. The AM display can use a vertical TFT structure such as a static induction transistor (SIT). The SIT and the display have the same electrode in common and can be disposed in the same substrate.

There is an article that discloses an arrangement of OTFT-OLED pixels based on a short chain pentacene material. This article is published in Applied Physics Letters, Vol. 83, No. 16, 2003-10-20, M. Kitamura. OTFT-OLED pixels show that the OLED is deposited on a substrate such as the OTFT. OLED pixels are formed in an upper, lower, or side part of the OTFT in the same substrate.

Above mentioned structures require manufacturing the OTFT and OLED in a continuous process. However, the OTFT and OLED cannot be simultaneously manufactured and tested. Also, such structure requires a space for disposing the OTFT near the OLED, which reduces the aperture ratio.

Conventional methods for manufacturing the AM type display of OTFT provide limited selection of manufacturing methods. OLED and OTFT formed on the same substrate may affect each other negatively. A high temperature process is required in some part when manufacturing an OLED. For example, a resin layer may be baked to form a pixel definition film. Also, a pixel electrode may be formed by sputtering. These processes can damage a previously formed organic material of the OTFT and may negatively affect the transistor characteristics.

U.S. Pat. No. 6,091,194 discloses an AM display having an OLED material disposed between an upper substrate and a lower substrate. The lower substrate includes a switching device, and the switching device is disposed in an outer surface of the lower substrate. A through hole is separately formed in the lower substrate to be connected with the switching device. When the AM display uses an organic transistor, it requires an additional encapsulation to protect the OTFT from moisture, oxygen, and dust.

U.S. Patent Publication No. US 2002/0079494 discloses an AMOLED display. The AMOLED display is based on a conventional TFT having a good filing structure. The TFT and the OLED are electrically connected to each other via an anisotropic conductive film. To this end, a comprehensive substrate preparation process is required to contact the conductive medium to the surface of the OLED. A substantial process of coupling the OLED and the OTFT requires vacuum, heat, pressure, or ultraviolet rays, thus making the coupling process complex. The organic transistor or inkjet technology cannot be used to couple the OLED and OTFT. Also, it requires an additional protective layer of the OLED.

### SUMMARY OF THE INVENTION

This invention provides an organic light emitting display device that can be controlled by thin film transistors, whereby the organic light emitting display device has a structure including an organic thin film transistor (OTFT) and an organic light emitting diode (OLED) that can be simultaneously manufactured and tested.

The present invention also provides an organic light emitting display device that can reduce manufacturing costs and a method for manufacturing the organic light emitting display device.

Additional features of the invention will be set forth in the description which follows, and in part will be apparent from the description, or may be learned by practice of the invention.

The present invention discloses a method for manufacturing an organic light emitting display device, including preparing a first substrate including an organic light emitting diode (OLED), preparing a second substrate including an organic thin film transistor (OTFT), forming a contact in at least one of the first substrate and the second substrate, and electrically connecting the first substrate and the second substrate using the contact.

The present invention also discloses an organic light emitting display device, including a first substrate including an OLED, a second substrate including an OTFT, and a contact disposed between the first substrate and the second substrate and electrically connecting the first substrate and the second substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A shows a cross-sectional view of an active matrix (AM) type organic light emitting display device according to an exemplary embodiment of the present invention before two substrates are connected to each other.

FIG. 1B shows a cross-sectional view of the AM type organic light emitting display device according to an exemplary embodiment of the present invention after two substrates are connected to each other.

FIG. 2 shows a cross-sectional view of a pixel used in an organic light emitting display device according to an exemplary embodiment of the present invention.

FIG. 3 shows a circuit diagram of a pixel circuit of the AM type organic light emitting display device according to an exemplary embodiment of the present invention.

FIG. 4 shows a circuit diagram of a pixel circuit of the AM type organic light emitting display device according to an exemplary embodiment of the present invention.

FIG. 5 shows a cross-sectional view of an AM type organic light emitting display device according to another exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element such as a layer, film, region or substrate is referred to as being “on” another element, it can be directly on the other element or intervening elements may also be present. In contrast, when an element is referred to as being “directly on” another element, there are no intervening elements present.

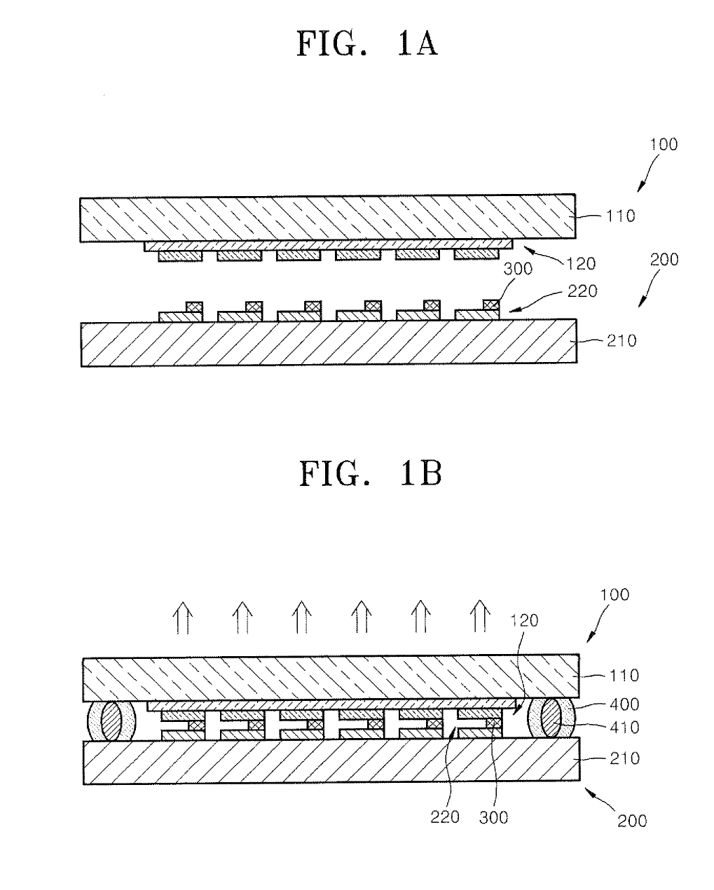

FIG. 1A shows a cross-sectional view of an active matrix (AM) type organic light emitting display device according to an exemplary embodiment of the present invention before two substrates are connected to each other. FIG. 1B shows a cross-sectional view of the AM type organic light emitting display device according to an exemplary embodiment of the present invention after two substrates are connected to each other.

Referring to FIG. 1A and FIG. 1B, to manufacture the AM type organic light emitting display device, an organic light emitting diode (OLED) substrate 100 and an organic thin film transistor (OTFT) substrate 200 are prepared. The OLED substrate 100 is a first substrate that may have an OLED that emits light directly. The OTFT substrate 200 is a second substrate that may include an OTFT and various pixel circuits that control a pixel signal.

The first substrate 100 includes an OLED 120 disposed on a surface facing the second substrate 200 of a first base material 110. The second substrate 200 includes an OTFT 220 disposed on a surface facing the first substrate 100 of a second base material 210.

The first base material 110 used to form the OLED 120 may be transparent and can be formed of transparent glass or plastic. The second base material 210 used to form the OTFT 220 can be transparent and can be formed of glass, plastic, or metal.

The first substrate 100 and the second substrate 200 are separately manufactured as illustrated in FIG. 1A and then connected to each other as illustrated in FIG. 1B. A contact 300 is formed in the second substrate 200 and electrically connects the OLED 120 of the first substrate 100 and the OTFT 220 of the second substrate 200. The contact 300 may be formed in the first substrate 100 instead of the second substrate 200, or may be formed in the first substrate 100 and the second substrate 200.

The first substrate 100 and the second substrate 200 are connected to each other using sealants 400 disposed in edges of the first and second substrate 100 and 200. The sealants 400 may include spacers 410 to establish a gap between the first substrate 100 and the second substrate 200. The AM type organic light emitting device of the current embodiment of the present invention may display an image in a direction of the first substrate 100, i.e. a direction indicated an arrow illustrated in FIG. 1B but the present invention is not limited thereto. The AM type organic light emitting device of the current embodiment can display the image in a direction of the second substrate 200 or both directions.

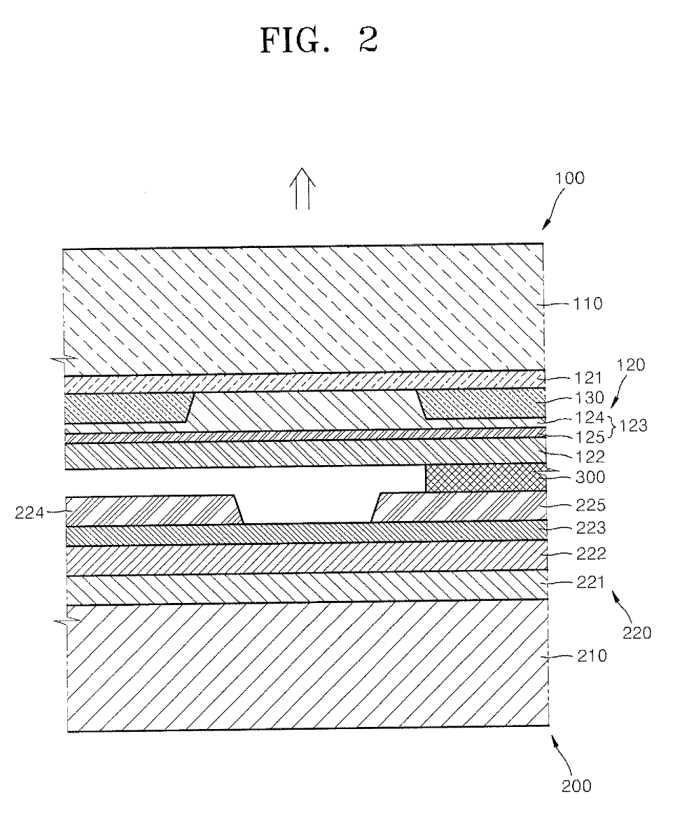

The first substrate 100, the second substrate 200, and the contact 300 will now be in detail described with reference to FIG. 2.

Regarding the first substrate 100 of FIG. 2, a first electrode 121 is formed in a portion of the first base material 110. A pixel definition film 130 having a predetermined opening is formed in a portion of the first electrode 121. An organic layer 123 is formed in a portion of the first electrode 121 that is exposed through the opening of the pixel definition film 130. The organic layer 123 may include a hole transport layer (HTL) 124 and an emission layer (EML) 125. A second electrode 122 is formed in a portion of the organic layer 123. The first electrode 121 serves as an anode electrode and the second electrode 122 serves as a cathode electrode, or vice versa.

The first electrode 121 may cover all pixels or may be formed individually corresponding to each pixel. It may be formed of a transparent conductor having a high work function, such as ITO, IZO, In₂O₃, or ZnO, by sputtering.

The pixel definition film 130 can be an organic insulation film, an inorganic insulation film, or an organic-inorganic-hybrid film, and may have a single layer structure or a multi-layer structure. When the pixel definition film 130 is applied to a flexible display, the pixel definition film 130 may be the organic insulation film.

A polymer material can be used as the organic insulation film. The polymer material can be selected from the group consisting of general polymers PMMA and PS, a polymer derivative having a phenol group, an acryl group polymer, an imide group polymer, an arylether group polymer, an amide group polymer, a fluorine group polymer, a p-xylyrene group polymer, a vinyl alcohol group polymer, and any blend of these materials.

The inorganic material can be at least one material selected from the group consisting of SiO₂, SiNₓ, SiON, Al₂O₃, TiO₂, Ta₂O₅, HfO₂, ZrO₂, BST, and PZT.

The pixel definition film 130 can be formed by inkjet printing. In this case, the surface of the first substrate 121 may be partially treated. A surface treatment process may use fluorine plasma to make the surface of the first substrate hydrophobic. The surface treatment process may use a fluorine gas such as CF₄ or C₃F₈. A liquid solution including an insulation material for the pixel definition film 130 is discharged from an inkjet head to form the pixel definition film 130 on the first electrode 121. The treated surface of the first substrate 121 does not allow formation of the insulation material. Therefore, the treated surface of the first substrate 121 becomes an opening that exposes the first substrate 121.

When the surface of the first electrode 121 or the surface of the first base material 110 is not properly adhered with an ink, the surface of the first electrode 121 or the surface of the first base material 110 can be treated excluding the opening exposing a part of the first electrode 121 to form the pixel definition film 130 having the opening.

In detail, the surface treatment process is performed in the first electrode 121 or the first base material 110 excluding the surface of the first electrode 121 corresponding to the opening using Ar and O₂ plasma. The treatment makes the surface of the first electrode 121 or the surface of the first base material 110 hydrophilic, thereby increasing adhesion between the ink and the surface of the first electrode 121 or the surface of the first base material 110. Thereafter, the ink including the insulation material is discharged to the surface of the substrates. This forms the pixel definition film 130 coated only in the part of increased adhesion. Therefore, the pixel definition film 130 is formed only on a surface of the first electrode 121 that is treated using plasma.

The formation of the pixel definition film 130 is not limited thereto. An insulation film is formed using a general method to form the opening using a photolithography method.

The organic layer 123 is formed on the first substrate 121 exposed through the opening of the pixel definition film 130.

The organic layer 123 can be a small molecular weight organic layer or a polymer organic layer. When the organic layer 123 is the small molecular weight organic layer, the organic layer 123 can include a hole injection Layer (HIL), a hole transport layer (HTL), an emission layer (EML), an electron transport layer (ETL), or an electron injection layer (EIL). It can be stacked in a single structure or a composite structure. It may comprise copper phthalocyanine (CuPc), N,N′-di(naphthalene-1-yl)-N,N′-diphenyl-benzidine (NPB), or tris-8-hydroxyquinoline aluminum (Alq3). The small molecular weight organic layer can be formed using a vacuum evaporation method.

The organic layer 123 of the current embodiment of the present invention can be the polymer organic layer and may include the HTL 124 and the EML 125. The HTL 124 can be formed of PEDOT, and the EML 125 can be formed of poly-phenylenevinylene (PPV) and polyfluorene. The polymer organic layer can be formed by screen printing, ink jet printing, etc.

The second electrode 122 is formed to cover the organic layer 123. The second electrode 122 can be formed of a reflective metal having a low work function, such as Ag, Mg, Al, Pt, Pd, Au, Ni, Nd, Ir, Cr, Li, Ca, or a compound of these metals. The second electrode 122 can be formed in each pixel via deposition using a mask but the present invention is not limited thereto. Liquid solution including metal powders, such as Ag, Mg, Cu, Au, Pt, Pd, or Ni, may be printed using the inkjet printing method, and baked to form the second electrode 122.

The second substrate 200 can include a structure in which a gate electrode 221, a gate insulation film 222, an organic semiconductor layer 223, a source electrode 224, and a drain electrode 225 are sequentially disposed in the second base material 210.

The gate electrode 221 can be formed by depositing a metal such as Ag, Mg, Al, Pt, Pd, Au, Ni, Nd, Ir, Cr, Li, Ca, a compound of these metals, or using a sputtering method, or printing the liquid solution including metal powders such as Ag, Mg, Cu, Au, Pt, Pd, or Ni, using the inkjet printing method, and baking the liquid solution.

The gate insulation film 222 is formed to cover the gate electrode 221. The gate insulation film 223 can be the organic insulation film, the inorganic insulation film, or the organic-inorganic-hybrid film, and have the single layer structure or the multi-layer structure.

The organic semiconductor layer 223 is formed on the gate insulation film 223 to be insulated from the gate electrode 221. Examples of the organic semiconductor include pentacene, tetracene anthracene, naphthalene, alpha-6-thiophen, alpha-4-thiophen, perylens and derivatives, rubrene and derivatives, coronene and derivatives, perylene tetracarboxylic diimide and derivatives, perylene tetracarboxylic dianhydride and derivatives, oligoacene of naphthalene and derivatives, oligothiophen of alpha-5-thiophen and derivatives, phthalocyanine containing or not containing metal and derivatives, naphthalene tetracarboxylic diimide and derivatives, pyromellitic dianhydride and derivatives, pyrometllitic diimide and derivatives, conjugate polymer containing thiophen and derivatives, and polymer including fluorine and derivatives.

The source electrode 224 and the drain electrode 225 may be formed separate from each other on the organic semiconductor layer 223. In consideration of the contact characteristic of the organic semiconductor layer 223, the source electrode 224 and the drain electrode 225 may include an electrode material having a higher work function than the organic semiconductor layer 223, and can include a metal selected from Au, Pt, and Pd.

The OTFT 220 is not limited to the structure mentioned above but to various structures including a top gate structure.

After the OTFT 220 is formed, the contact 300 is formed in one of the source electrode 224 and the drain electrode 225. The contact 300 is formed in the drain electrode 225 as illustrated in FIG. 2 but the present invention is not limited thereto.

The contact 300 electrically couples the first substrate 100 and the second substrate 200 and can be formed of a conductive resin using dispenser technology. The conductive resin, for example a conductive epoxy, can include a conductor such as silver or carbon, and include an adhesion material based on an epoxy, acryl, urethane, or silicon material.

The contact 300 can be formed by inkjet-printing a liquid solution including metal particles or using conductive polymer.

A hydrosphere metal liquid solution or a metal solution is appropriate for the inkjet printing based on an organic solvent or suspension (ink) and can include a metal compound, an ion compound, or a compound of the metal compound and the ion compound. The hydrosphere metal liquid solution or the metal solution is printed and baked to obtain metal conductivity of the contact 300. The contact 300 can be formed of Ag, Au, Pt, Pd, Cu, or Ni.

An example of the conductive polymer is a conductive rubber and has a structure in which a conductive film and a non-conductive film tightly contact each other. The conductive polymer is cost effective and can be quickly coated. The conductive polymer is not sensitive to corrosion, and can absorb an external vibration or shock.

The contact 300 may cover between 1% and 50% of a pixel area, may cover between 1% and 25% of the pixel area, or may cover between 1% and 20% of the pixel area. A pixel area may include an area within a single pixel. The pixel area may include an area within the pixel that emits light and an area within the pixel that does not emit light.

Since a material of the contact 300 may be flexible during the manufacturing process, the contact 300 may be useful in connecting the first substrate 100 and the second substrate 200. In detail, although each connected part of the two substrates may be rough or is not flat, the contact 300 may smooth the connected parts to easily connect the first substrate 100 and the second substrate 200.

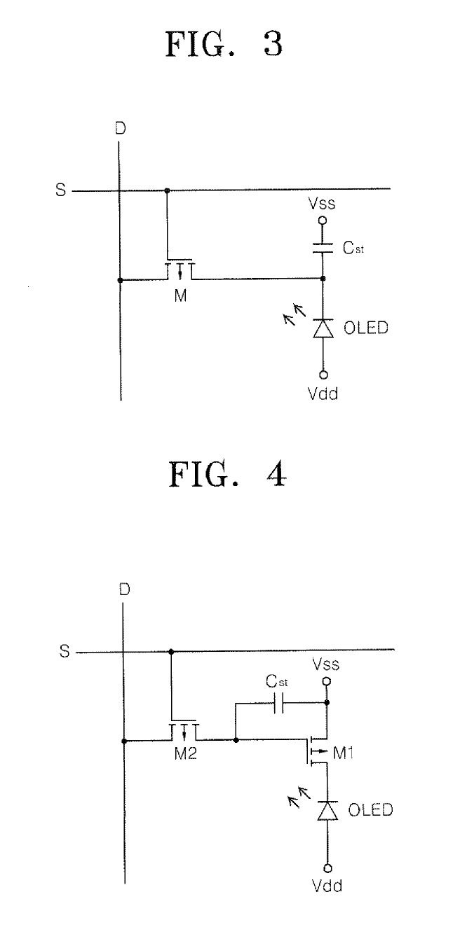

The second substrate 200 can include a variety of pixel circuits including the OTFT 220. FIG. 3 is a circuit diagram of a transistor pixel circuit. Select line S and data line D cross each other. A gate electrode of switching transistor M may be connected to the select line S and a source electrode of the switching transistor M may be connected to the data line D. If a select signal is applied to the select line S, the switching transistor M is turned on, a data signal is connected to an OLED through the data line D, and a storage capacitor Cst connected to a drain electrode of the switching transistor M is charged. A driving voltage Vss is applied to another node of the storage capacitor Cst and a differential value is charged. When the switching transistor M is turned off, the OLED is driven using a voltage value charged in the storage capacitor Cst. Another driving voltage Vdd may be applied to another node of the OLED.

Referring to FIG. 4, the pixel circuit may have two transistors. A gate electrode of switching transistor M2 may be connected to the select line S and a source electrode of the switching transistor M2 may be connected to the data line D. A drain electrode of driving transistor M1 is connected to an OLED.

These transistors are the OTFTs mentioned above and can be formed at the same time when forming the storage capacitor, the gate electrode and the drain electrode of the OTFT.

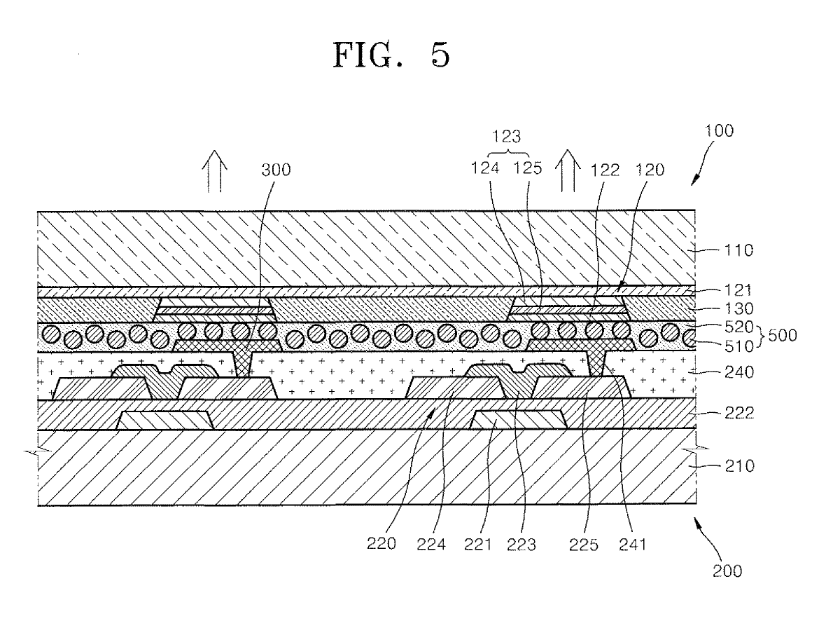

FIG. 5 is a cross-sectional view of an AM type organic light emitting display device according to another embodiment of the present invention.

In a first substrate 100 of FIG. 5, a first electrode 121 is formed in a first base material 110 over the entire pixels. A pixel definition film 130 having an opening corresponding to each pixel is formed in the first electrode 121. An organic layer 123 and a second electrode 122 are sequentially inkjet printed in the opening region formed in the pixel definition film 130. The organic layer 123, particularly an EML 125, and the second electrode 122 can be patterned to easily correspond to the pixel. The organic layer 123 and the second electrode 122 can be formed using a Laser Induced Thermal Imaging (LITI) method.

For a second substrate 200, a gate electrode 221 is formed on a second base material 210 and a gate insulation film 222 is formed to cover the gate electrode 221. A source electrode 224 and a drain electrode 225 are formed on the gate insulation film 222, and an organic semiconductor layer 223 is formed on the source electrode 224 and the drain electrode 225. A protective film 240 is formed on the gate insulation film 222 to cover the source electrode 224, the drain electrode 225 and the organic semiconductor layer 223. The protective film 240 can be an organic insulation film, an inorganic insulation film, and a compound of these films like the pixel definition film 130. A contact hole 241 is formed in the protective film 240, and a contact 300 is formed in the protective film 240 so that the contact 300 may contact the source electrode 224 or the drain electrode 225. Alternatively, a protective film may be formed on the first substrate 100 to cover a pixel definition film 130. In such a case, a contact hole is formed in the protective film to contact a second electrode 122 through the protective film.

After the contact 300 is formed, an anisotropic conductive material 500 may be disposed between the first substrate 100 and the second substrate 200 to connect the first substrate 100 and the second substrate 200. The anisotropic conductive material 500 may include adhesives 520 and a plurality of conductive balls 510. The conductive balls 510 are pressed by the coalescence of the first substrate 100 and the second substrate 200 to electrically couple the contact 300 and the second substrate 122. Therefore, the AM type organic light emitting display device can be easily manufactured.

According to the present invention, an organic light emitting display device can be manufactured at low costs, using a simplified manufacturing process.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method for manufacturing an organic light emitting display device, comprising:
preparing a first substrate including an organic light emitting diode (OLED);
preparing a second substrate including an organic thin film transistor (OTFT);
forming a contact in at least one of the first substrate and the second substrate; and
electrically coupling the first substrate and the second substrate using the contact.

2. The method of claim 1, wherein preparing the first substrate comprises:
forming a first electrode on a first base material;
forming an organic layer including an emissive layer (EML) on the first electrode; and
forming a second electrode on the organic layer,
wherein the contact electrically couples the second substrate to the second electrode of the first substrate.

3. The method of claim 1, wherein preparing the second substrate comprises:
forming a source electrode; and
forming a drain electrode,
wherein the contact electrically couples the first substrate to one of the source electrode and the drain electrode of the second substrate.

4. The method of claim 1, wherein the contact comprises a conductive resin and is formed using a dispenser.

5. The method of claim 1, wherein the contact comprises a liquid solution including metal particles and is formed by inkjet printing.

6. The method of claim 1, wherein the contact comprises conductive polymer.

7. The method of claim 1, further comprising:
sealing a space between the first substrate and the second substrate.

8. The method of claim 7, wherein the first substrate and the second substrate are sealed via sealants formed along edges of the first substrate and the second substrate.

9. The method of claim 1, wherein the first substrate and the second substrate are electrically coupled by disposing an anisotropic conductive adhesive member between the first substrate and the second substrate and adhering the first substrate to the second substrate.

10. An organic light emitting display device, comprising:
a first substrate including an OLED;
a second substrate including an OTFT; and
a contact disposed between the first substrate and the second substrate and electrically coupling the first substrate and the second substrate.

11. The organic light emitting display device of claim 10, wherein the first substrate comprises:
a first base material;
a first electrode disposed in a portion of the first base material;
an organic layer including an EML, disposed in a portion of the first electrode; and
a second electrode disposed in a portion of the organic layer,
wherein the contact is electrically coupled to the second electrode.

12. The organic light emitting display device of claim 10, wherein the second substrate comprises:
a source electrode; and
a drain electrode,
wherein the contact is electrically coupled to one of the source electrode and the drain electrode.

13. The organic light emitting display device of claim 10, wherein the contact comprises a conductive resin.

14. The organic light emitting display device of claim 10, wherein the contact comprises a liquid solution including metal particles.

15. The organic light emitting display device of claim 10, wherein the contact comprises conductive polymer.

16. The organic light emitting display device of claim 10, wherein a space between the first substrate and the second substrate is sealed.

17. The organic light emitting display device of claim 16, wherein the first substrate and the second substrate are sealed by sealants positioned along edges of the first substrate and the second substrate.

18. The organic light emitting display device of claim 17, wherein the sealants include spacers.

19. The organic light emitting display device of claim 10, wherein an anisotropic conductive adhesive member is disposed between the first substrate and the second substrate.

20. The organic light emitting display device of claim 10, further comprising:
a protective film covering a surface of the first substrate and the second substrate,
wherein the contact is disposed on the protective film.
